(19) United States
(12) Patent Application Publication
(10) Pub. No.: US 2023/0369051 A1
(43) Pub. Date: Nov. 16, 2023

(54) FABRICATION METHOD AND STRUCTURE OF SEMICONDUCTOR DEVICE

(71) Applicant: CHANGXIN MEMORY TECHNOLOGIES, INC., Hefei (CN)

(72) Inventor: Yi TANG, Hefei (CN)

(21) Appl. No.: 17/875,432

(22) Filed: Jul. 28, 2022

(30) Foreign Application Priority Data
May 12, 2022 (CN) 202210520458.4

(51) Int. Cl. H01L 21/265; H01L 21/02

(52) U.S. Cl. CPC H01L 21/26513; H01L 21/02532

(57) ABSTRACT

Embodiments provide a method for fabricating a semiconductor device and a semiconductor device structure, and relates to the field of ion implantation technology. A method for fabricating a semiconductor device includes: providing a substrate; forming an active layer on a side of the substrate; forming, on a side of the active layer away from the substrate, a shielding layer covering the active layer; and performing ion implantation of a first element above the shielding layer to form a heavily doped layer on a surface of the active layer. An implantation depth corresponding to a peak implantation concentration of the first element is equal to a thickness of the shielding layer. The heavily doped layer can reduce an oxidation rate of the active layer to a certain extent, thereby improving yield of the semiconductor device.

### CROSS-REFERENCE TO RELATED APPLICATION

This application claims priority to Chinese Patent Application No. 202210520458.4, titled “FABRICATION METHOD AND STRUCTURE OF SEMICONDUCTOR DEVICE” and filed to the State Patent Intellectual Property Office on May 12, 2022, the entire contents of which are incorporated herein by reference.

### TECHNICAL FIELD

The present disclosure relates to the field of ion implantation technology, and more particularly, to a method for fabricating a semiconductor device and a semiconductor device structure.

### BACKGROUND

In the process of fabricating semiconductor devices, silicon germanium layers and silicon substrates generally need to be separated by thermal oxide layers, to avoid an unnecessary interface states caused by direct contact between the silicon germanium layers and the silicon substrates. For the silicon germanium layers, the oxidation rate of silicon germanium is higher than that of silicon. Therefore, in the prior art, the silicon germanium is generally passivated by means of rapid thermal hydrogenation or rapid thermal nitridation, such that the oxidation rate of silicon germanium is equal to that of silicon. However, introduction of hydrogen atoms and nitrogen atoms will cause degradation, leakage and a series of reliability problems of the semiconductor device.

The above-mentioned information disclosed in this Background section is only for the purpose of enhancing the understanding of background of the present disclosure and may therefore include information that does not constitute prior art known to those of ordinary skill in the art.

### SUMMARY

An objective of the present disclosure is to provide a method for fabricating a semiconductor device and a semiconductor device structure.

To achieve the foregoing objective, the present disclosure adopts the following technical solutions.

According to a first aspect of the present disclosure, there is provided a method for fabricating a semiconductor device, and the fabrication method includes:
providing a substrate;
forming an active layer on a side of the substrate;
forming, on a side of the active layer away from the substrate, a shielding layer covering the active layer; and
performing ion implantation of a first element above the shielding layer to form a heavily doped layer on a surface of the active layer.

An implantation depth corresponding to a peak implantation concentration of the first element is equal to a thickness of the shielding layer.

According to a second aspect of the present disclosure, there is provided a semiconductor device structure fabricated by using the above-mentioned fabrication method, wherein the semiconductor device structure includes:
a substrate;
an active layer positioned on the substrate;
a heavily doped layer positioned on a surface of the active layer away from the substrate; and
an interface layer positioned above the surface of the active layer, the heavily doped layer being positioned between the active layer and the interface layer.

### BRIEF DESCRIPTION OF THE DRAWINGS

To describe the technical solutions of the embodiments of the present disclosure or those of the prior art more clearly, the accompanying drawings required for describing the embodiments or the prior art will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a flowchart of a method for fabricating a semiconductor device according to an embodiment of the present disclosure;

FIG. 2 is a schematic structural diagram of forming an active layer according to an embodiment of the present disclosure;

FIG. 3 is a schematic structural diagram of forming a shielding layer according to an embodiment of the present disclosure;

FIG. 4 is a schematic structural diagram of forming a heavily doped layer according to an embodiment of the present disclosure;

FIG. 5 is a schematic structural diagram of removing the shielding layer according to an embodiment of the present disclosure;

FIG. 6 is a schematic structural diagram of forming an interface layer, a dielectric layer and a gate stack layer according to an embodiment of the present disclosure; and

FIG. 7 is a coordinate graph showing the relationship between ion implantation depth and silicon ion concentration according to an embodiment of the present disclosure.

Reference numbers of main components in the accompanying drawings are as follows:
10—substrate; 20—active layer; 30—shielding layer; 40—heavily doped layer; 50—interface layer; 60—dielectric layer; and 70—gate stack layer.

### DETAILED DESCRIPTION

The exemplary embodiments will now be described more fully with reference to the accompanying drawings. However, the exemplary embodiments can be implemented in a variety of forms and should not be construed as being limited to the embodiments set forth herein. Rather, these embodiments are provided such that the present disclosure will be thorough and complete and will fully convey the concepts of exemplary embodiments to those skilled in the art. The features, structures, or characteristics described may be combined in one or more embodiments in any suitable manner. In the following description, numerous concrete details are provided to give a full understanding of the embodiments of the present disclosure.

In drawings, thickness of areas and layers may be exaggerated for clarity. The same numbers in drawings represent the same or similar structures, and thus detailed description thereof is omitted.

The features, structures, or characteristics described may be combined in one or more embodiments in any suitable manner. In the following description, numerous concrete details are provided to give a full understanding of the embodiments of the present disclosure. However, those skilled in the art will appreciate that the technical solutions in the present disclosure may be practiced without one or more of the concrete details, or other methods, elements, materials and so on may be employed. In other circumstances, known structures, materials or operations are not shown or described in detail for the avoidance of fuzziness of the main technological creativity of the present disclosure.

When a certain structure is “above” other structures, it likely means that the certain structure is integrally formed on the other structures, or the certain structure is “directly” arranged on the other structures, or the certain structure is “indirectly” arranged on the other structures by means of another structure.

The terms “one”, “a” and “the” are intended to mean that there exists one or more elements/constituent parts/etc. The terms “comprising” and “having” are intended to be inclusive and mean that there may be additional elements/constituent parts/etc. other than the listed elements/constituent parts/etc. The terms “first” and “second” and so on are merely used as labels, and do not impose numerical limitations on objects thereof.

In the process of fabricating semiconductor devices, silicon germanium layers and silicon substrates 10 generally need to be separated by thermal oxide layers, to avoid an unnecessary interface states caused by direct contact between the silicon germanium layers and the silicon substrates 10. For the silicon germanium layers, the oxidation rate of silicon germanium is higher than that of silicon. Therefore, in the prior art, the silicon germanium is generally passivated by means of rapid thermal hydrogenation or rapid thermal nitridation, such that the oxidation rate of silicon germanium is equal to that of silicon. However, the introduction of hydrogen atoms and nitrogen atoms will cause degradation, leakage and a series of reliability problems of the semiconductor device.

Embodiments of the present disclosure provide a method for fabricating a semiconductor device, as shown in FIG. 1, the fabrication method may include:
Step S110: providing a substrate 10;
Step S120: forming an active layer 20 on a side of the substrate 10;
Step S130: forming, on a side of the active layer 20 away from the substrate 10, a shielding layer 30 covering the active layer 20; and
Step S140: performing ion implantation of a first element above the shielding layer 30 to form a heavily doped layer 40 on a surface of the active layer 20; wherein an implantation depth corresponding to a peak implantation concentration of the first element is equal to a thickness of the shielding layer 30.

In the present disclosure, ions of the first element are implanted into the active layer 20 by means of an ion implantation technology above the shielding layer 30, where an implantation depth corresponding to a peak implantation concentration of the first element is equal to a thickness of the shielding layer 30. After the ions are implanted into the shielding layer 30, the ion implantation speed slows down as energy of the implanted ions is gradually consumed. Because the implantation depth corresponding to the peak implantation concentration of the first element is equal to the thickness of the shielding layer 30, more ions exactly stop on a surface of the active layer 20 after moving a certain distance in the shielding layer 30, thereby forming the heavily doped layer 40 on the surface of the active layer 20. The heavily doped layer 40 can reduce the oxidation rate of the active layer 20 to a certain extent, thereby improving yield of the semiconductor device.

Each step of the method for fabricating a semiconductor device provided by the embodiments of the present disclosure will be described in detail below with reference to the accompanying drawings.

In one embodiment of the present disclosure, the substrate 10 may have a flat plate structure, and its shape may be rectangular, circular, elliptical or irregular, and of course, may be other shapes, which are not enumerated here.

The substrate 10 may be made of at least one of following materials: silicon, silicon on insulator (SOI), stacked silicon on insulator (SSOI), stacked silicon germanium on insulator (S-SiGeOI), silicon germanium on insulator (SiGeOI), germanium on insulator (GeOI), and the like. In the present disclosure, the silicon-on-insulator (SOI) may be adopted, and the support substrate 10, an oxide insulating layer and a semiconductor material layer are sequentially arranged from bottom to top of the silicon-on-insulator (SOI), but it is not limited to the above example.

In some embodiments, at step S110, the substrate 10 may include a first element, and the active layer 20 may include the first element and a second element, and a content of the first element in the active layer 20 may be greater than a content of the second element.

In some embodiments, both the first element and the second element may include silicon and germanium. In some embodiments, the first element may include silicon. That is, the substrate 10 may include silicon, and the active layer 20 may include silicon and germanium. The content of silicon in the active layer 20 may be greater than the content of germanium. Because the oxidation rate of silicon germanium is higher than that of silicon, a quality of the fabricated active layer 20 is reduced. Therefore, in the present disclosure, ion implantation of silicon is performed on the shielding layer 30 to form the heavily doped layer 40 on the surface of the active layer 20, where the heavily doped layer 40 includes silicon ions. The heavily doped layer 40 can increase the concentration of silicon on the surface of the active layer 20, and the heavily doped layer 40 can protect the silicon germanium material inside the active layer 20, such that the oxidation rate of silicon germanium in the active layer 20 is reduced to some extent, thereby improving the quality of the active layer 20 and the yield of semiconductor device.

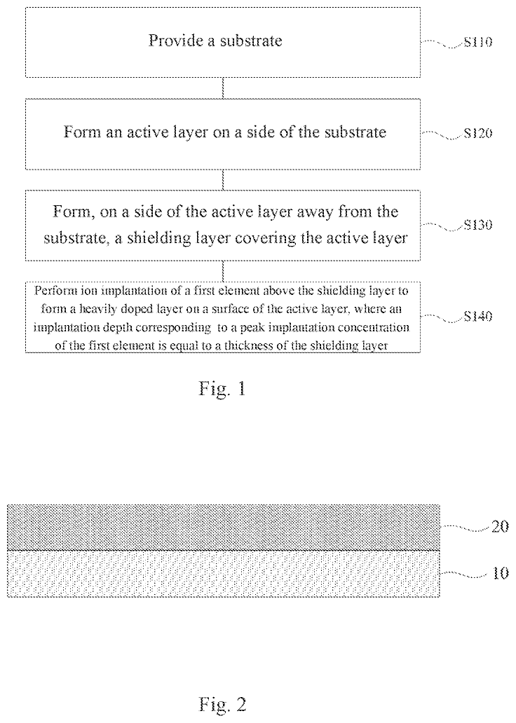

In some embodiments, as shown in FIG. 2, the active layer 20 is formed on a side of the substrate 10, and the active layer 20 may be formed by depositing on the substrate 10 for a first preset time by means of chemical vapor deposition using a gas containing the first element and a gas containing the second element. In some embodiments, the gas containing the first element and the gas containing the second element are introduced into a reaction chamber, where the two gases may produce a chemical reaction in the reaction chamber. Reactants generated by the chemical reaction can be deposited on the substrate 10, thereby forming the active layer 20. It is worth noting that the chemical reaction in the present disclosure occurs on the surface of the substrate 10 or in a region very close to the surface, such that a high-quality thin film (that is, the high-quality active layer 20) can be generated. If the chemical reaction occurs farther away from the surface of the substrate 10, it will result in poorer adhesion and lower density of the reactants produced by the chemical reaction, which may result in a series of defects of the active layer 20.

In some embodiments, the active layer 20 may be a silicon germanium layer, and the substrate 10 may be a substrate 10 containing silicon. In the present disclosure, the silicon germanium layer may be formed by depositing on the substrate 10 for a first preset time by means of chemical vapor deposition using a gas containing silicon and a gas containing germanium. In the silicon germanium layer, the content of silicon is greater than that of germanium.

In some embodiments, depending on a pressure of the reaction chamber and a reaction energy provided, the chemical vapor deposition in the present disclosure may include atmospheric pressure chemical vapor deposition, low pressure chemical vapor deposition, and plasma-assisted chemical vapor deposition. The plasma-assisted chemical vapor deposition may include plasma-enhanced chemical vapor deposition and high-density plasma chemical vapor deposition. The present disclosure is not particularly limited here, and a person skilled in the art may select a chemical vapor deposition method that matches the pressure of the reaction chamber.

In some embodiments, according to different heating modes of the reaction chamber, the reaction chamber in the present disclosure may include a hot-wall reaction chamber and a cold-wall reaction chamber. In some embodiments, a heating method used in the hot-wall reaction chamber refers to forming a hot-wall reactor by surrounding the reaction chamber by a thermal resistor, which not only heats a silicon wafer, but also heats a support of the silicon wafer and side walls of the reaction chamber. This mode may form a film on the side walls of the reaction chamber, such that particle contamination of the reaction chamber may be reduced by means of frequent cleaning or in-situ removal. However, the cold-wall reaction chamber only heats the silicon wafer and the support of the silicon wafer, and a sidewall temperature of the reaction chamber is so low that there is no enough energy to support a deposition reaction. For example, radio frequency (RF) induction heating or infrared heating may be used in the reaction chamber.

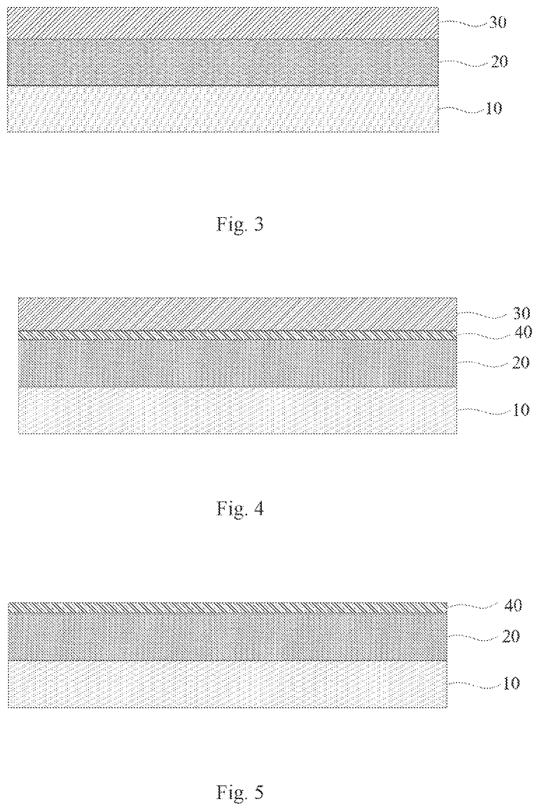

In some embodiments, at step S130, as shown in FIG. 3, the shielding layer 30 covering the active layer 20 is formed on the side of the active layer 20 away from the substrate 10. In some embodiments, the side of the active layer 20 away from the substrate 10 may be deposited by means of chemical vapor deposition for a second preset time to form the shielding layer 30 covering the active layer 20. The shielding layer 30 may prevent impurities from diffusing into the substrate 10, thereby shielding and masking the impurities.

In some embodiments, a material forming the shielding layer 30 may include a combination of one or more of oxides, nitrides, oxynitrides, oxycarbides, hydroxides or amorphous carbons. The present disclosure is not particularly limited here, and a person skilled in the art may select different materials according to different actual requirements.

In some embodiments, a thickness of the shielding layer 30 may range from 1 nm to 500 nm. For example, the thickness of the shielding layer 30 may be 1 nm, 10 nm, 100 nm, 200 nm, or 400 nm. In the present disclosure, the thickness of the shielding layer 30 may be selected correspondingly according to different ion implantation depths.

In some embodiments, at step S140, as shown in FIG. 4, a heavily doped layer 40 is formed by means of an ion implantation technology, where the heavily doped layer 40 may be positioned between the active layer 20 and the shielding layer 30. In some embodiments, forming the heavily doped layer 40 may include implanting ions corresponding to the first element into the shielding layer 30 at a preset angle by means of ion implantation technology using the gas containing the first element. In some embodiments, the gas containing the first element may be ionized and accelerated to have a certain energy by means of a magnetic field and an electric field to form an ion beam current with a certain current density and kinetic energy, and the ion beam current is directly implanted into the shielding layer 30. However, after the ions with certain kinetic energy are implanted into the shielding layer 30, the energy of the implanted ion beam current is gradually consumed due to an irregular action between nuclei and electrons in the shielding layer 30 and multiple collisions between atoms. With the continuous consumption of the energy, speed of the ion beam current slows down, and after moving a certain distance in the shielding layer 30, the ion beam current stops at a certain position from the substrate 10, thereby forming a PN junction. In the present disclosure, a doping source may be flexibly selected by using the ion implantation technology, and a doping concentration range can be increased. That is, the ion implantation can achieve accurate control whether for light doping or heavy doping. In addition, the concentration and the dose of the ion implantation are controllable in the process of the ion implantation, and thus accuracy of spatial positioning can be improved.

In some embodiments, when the first element is silicon, the gas containing silicon may be silane or silicon tetrafluoride. Of course, other gases containing silicon may be also acceptable, and the present disclosure is not particularly limited thereto.

In some embodiments of the present disclosure, when ions corresponding to the first element are implanted into the shielding layer 30 at a preset angle by means of an ion implantation technology, some problems such as channel effects, crystal defects or particle contamination may be caused because the ion implantation relies on higher kinetic energy to implant the ions into the shielding layer 30. For example, the channel effect refers to that a fact the arrangement of crystalline silicon atoms has a long-range order. When impurity ions are implanted through the channels in lattice gaps without colliding with electrons or nuclei (with less energy loss), the impurity ions will not slow down and thus enter deeper places in silicon, greatly exceeding an expected range, i.e., exceeding a designed junction depth, which is called the channel effect. In view of the above channel effect, in the present disclosure, when ion implantation is performed, the ions containing the first element are not vertically implanted into the shielding layer 30, instead the ions are deviated from a central axis of the shielding layer 30 by a certain angle, such that the channel effect can be reduced, thereby obtaining desired junction characteristics. For example, in the present disclosure, angle of deviation of neutrons from the central axis of the shielding layer 30 may range from 15° to 35°. For example, the angle of deviation may be 15°, 20°, 30° or 35°. Of course, other angles may also be acceptable, which is not specially limited here, so long as the angle is within the above range.

In some embodiments, during ion implantation, relationships between dose of ion implantation, size of the beam current and time of ion implantation may be expressed by the following formula:

$$D = \frac{It}{Aeq}$$

where A denotes an implantation area, q denotes a valence number of the ions implanted, e denotes quantity of one charge, D denotes the dose of the ions implanted, and t denotes the time of ion implantation.

As can be seen from the above, under the same implantation area, the size of the implanted beam current and the time of ion implantation directly determine the dose of ion implantation. The larger the beam current is, the longer the implantation time is, and the larger the dose is. Therefore, in the present disclosure, a dose in tens of millions may be achieved by controlling the beam current size and the implantation time.

In some embodiments, in the present disclosure, current of ion beam may be measured by using a Faraday cup sensor to monitor the dose in real time, to achieve uniformity of the ion implantation. Of course, the dose may be monitored in real time in other way, and the present disclosure is not particularly limited here.

In some embodiments of the present disclosure, the dose of the ion implantation is 10¹⁵ to 10¹⁸/cm², the energy of the ion implantation is 1 keV to 500 keV, and the temperature of the ion implantation is −40° C. to 140° C. Exemplarily, the dose of the ion implantation may be 10¹⁵/cm², 10¹⁶/cm², 10¹⁷/cm² or 10¹⁸/cm². Of course, other implantation doses may also be acceptable, which are not listed here. Exemplarily, the energy of the ion implantation may be 1 keV, 10 keV, 100 keV, 300 keV or 500 keV. Of course, other implanted energy may also be acceptable, which is not particularly limited here. Exemplarily, the temperature of the ion implantation may be −40° C., 50° C., 100° C., 130° C. or 140° C. As can be seen, the present disclosure can effectively increase a temperature range by means of the ion implantation technology, and doping can be performed not only in a low temperature range but also in a high temperature range. Of course, other temperature of ion implantation may also be acceptable, which is not particularly limited here.

In some embodiments, at step S140, the implantation depth corresponding to the peak implantation concentration of the first element is equal to the thickness of the shielding layer 30. For example, when the first element is silicon, a coordinate graph showing the relationship between ion implantation depth and concentration of silicon is shown in FIG. 7. In FIG. 7, an abscissa H represents the depth of the ion implantation, and an ordinate C represents the concentration of silicon. As can be seen from FIG. 7, when the depth of the ion implantation is A, the concentration of silicon reaches a peak. Therefore, by using the above relationship in the present disclosure, silicon can be exactly implanted into the surface of the active layer 20 by ensuring the implantation depth A corresponding to the peak concentration of silicon to be equal to the thickness of the shielding layer 30, thereby forming the heavily doped layer 40 configured to protect the active layer 20. Of course, the first element in the present disclosure may be other elements in addition to silicon. A person skilled in the art can also exactly implant the first element into the surface of the active layer 20 according to the technical concept provided by the present disclosure, that is, the implantation depth corresponding to the peak implantation concentration of the first element is equal to the thickness of the shielding layer 30.

In some embodiments, ions containing the first element may be implanted into the shielding layer 30 by using an ion implanter. According to a range of implant dose and energy, the ion implanter in the present disclosure may be a large beam current ion implanter, a high energy ion implanter, or a medium beam current ion implanter. The ion beam obtained by the high-energy implanter has higher energy. Generally, the energy of univalent ions can reach 500 keV to 1.2 meV after special acceleration. The large beam current implanter can obtain larger ion beam current, which has a larger doping concentration. The medium beam current implanter can obtain ion beam having medium energy and current, which are suitable for all ion doping processes.

In some other embodiments of the present disclosure, ions containing the first element may also be diffused into the shielding layer 30 by means of a diffusion technology to form the heavily doped layer 40 on the surface of the active layer 20. In some embodiments, the diffusion refers to diffusion movement of atoms, molecules and ions from a higher concentration to a lower concentration. Therefore in the present disclosure, during the diffusion, the ions containing the first element are diffused into the shielding layer 30 based on a predetermined concentration difference and a predetermined energy, such that the heavily doped layer 40 is formed on the surface of the active layer 20. When the ions containing the first element are diffused by using the diffusion technology, costs required for the diffusion can be greatly reduced because the diffusion process is relatively simple.

In some embodiments, a material of the shielding layer 30 in the present disclosure may be silicon dioxide or silicon nitride, which have a characteristic of high temperature resistance. Therefore, the shielding layer 30 can meet requirements of high temperature during the diffusion.

In some embodiments, step S140 may further include step S150.

At step S150, after the ion implantation is completed, thermal annealing is performed on the semiconductor structure. In some embodiments, one of the following methods may be selected: pulsed laser rapid annealing, pulsed electron beam rapid annealing, ion beam rapid annealing, continuous wave laser rapid annealing and incoherent broadband light source (such as halogen lamp, arc lamp and graphite heating) rapid annealing, and the like. A person skilled in the art may make selections as required, which are not limited to the examples listed.

In some embodiments, the annealing temperature is 800° C. to 1100° C., and the annealing time is 1 s to 30 s. In some embodiments, the annealing temperature may be 800° C., 900° C., 1000° C. or 1100° C.; and in one embodiment, to effectively reduce further diffusion of the ions to the substrate 10, the annealing time may be 1 s to 30 s. The annealing time may be 1 s, 5 s, 10 s, 20 s, or 30 s. of course, other annealing time may also be acceptable, which is not to be enumerated here.

In some embodiments, step S140 may further include step S160.

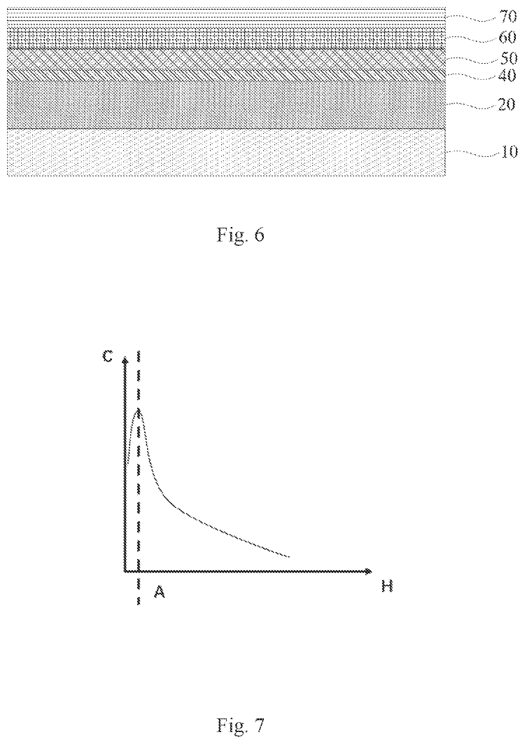

At S160, as shown in FIGS. 5 to 6, after the thermal annealing, the shielding layer 30 is removed. An interface layer 50 is formed on the side of the active layer 20 away from the substrate 10, and a dielectric layer 60 and a gate stack layer 70 are sequentially formed above the interface layer 50. The interface layer 50 is positioned above the heavily doped layer 40, that is, the heavily doped layer 40 is positioned between the interface layer 50 and the active layer 20. In addition, the dielectric layer 60 and the gate stack layer 70 are positioned above the interface layer 50 in sequence, and the dielectric layer 60 is positioned between the gate stack layer 70 and the interface layer 50. Because the heavily doped layer 40 containing the first element is formed on the surface of the active layer 20, the concentration of the first element is higher, and a higher concentration of the first element can meet growth of the dielectric layer 60 and the gate stack layer 70, thereby meeting quality requirements of the dielectric layer 60 and the gate stack layer 70.

The embodiments of the present disclosure also provide a semiconductor device structure, which may be fabricated using the aforementioned fabrication method. The semiconductor device structure may include:
a substrate 10;
an active layer 20 positioned on the substrate 10;
a heavily doped layer 40 positioned on a surface of the active layer 20 away from the substrate 10; and
an interface layer 50 positioned above the surface of the active layer 20, where the heavily doped layer 40 is positioned between the active layer 20 and the interface layer 50.

The heavily doped layer 40 of the semiconductor device structure of the present disclosure can well protect the active layer 20 from being oxidized, thereby improving the yield of the semiconductor device.

In some embodiments, a thickness of the heavily doped layer 40 may be smaller than that of the interface layer 50. The thickness of the interface layer 50 may be smaller than that of the active layer 20.

In some embodiments, the semiconductor device structure may further include a dielectric layer 60 and a gate stack layer 70, where the dielectric layer 60 may be positioned above the interface layer 50, and the gate stack layer 70 may be positioned above the dielectric layer 60. That is, the heavily doped layer 40 is positioned between the active layer 20 and the interface layer 50, the interface layer 50 is positioned between the heavily doped layer 40 and the dielectric layer 60, and the dielectric layer 60 is positioned between the interface layer 50 and the gate stack layer 70.

In some embodiments, the dielectric layer 60 may be silicon oxide (SiO₂) or silicon oxynitride (SiON). The dielectric layer 60 made of silicon oxide may be formed by means of oxidation processes known to a person skilled in the art, such as furnace tube oxidation, rapid thermal annealing oxidation (RTO), in-situ steam oxidation (ISSG), and the like. Next, the gate stack layer 70 is deposited, where the gate stack layer 70 includes a multilayer structure of semiconductor materials, such as silicon, tungsten or a combination thereof. The gate stack layer 70 and a gate material layer are etched to form a gate structure. After the gate structure is formed, spacer walls are formed on two sides of the gate, and the spacer walls may be one of silicon oxide, silicon nitride, and silicon oxynitride, or a combination thereof. As an optimized implementation of this embodiment, the spacer walls comprise silicon oxide and silicon nitride.

In some embodiments, the substrate 10 may include a silicon substrate 10, the active layer 20 may include a silicon germanium layer, and the heavily doped layer 40 may include a silicon layer. Accordingly, the semiconductor device structure may include:
a silicon substrate 10;
a silicon germanium layer positioned on the silicon substrate 10;
a silicon layer positioned on a surface of the silicon germanium layer away from the silicon substrate 10; and
an interface layer 50 positioned above the surface of the silicon germanium layer, where the silicon layer is positioned between the silicon germanium layer and the interface layer 50.

In the embodiments of the present disclosure, by controlling the implantation depth corresponding to a maximum ion implantation concentration of silicon, which is equal to the depth of the shielding layer, silicon ions can be best implanted into the surface of the silicon germanium layer, and a heavily doped layer with a larger concentration of Si ions can be obtained on the surface of the silicon germanium layer, such that the content of Si in the heavily doped layer is close to that of the silicon substrate. Due to the existence of the silicon layer formed on the surface of the silicon germanium layer, in one aspect, the interface layer between a channel and the gate stack structure is generally made of oxide material. For example, the interface layer is formed by silicon dioxide. At this moment, because the heavily doped layer is almost a silicon layer, an interface layer oxide may be directly grown on the surface of the silicon layer, and quality of the grown interface layer oxide may be equivalent to that of a silicon channel oxide. In another aspect, the silicon layer on the surface can also protect the silicon germanium layer therebelow, and the oxidation rate of SiGe is higher than that of Si. Therefore, the existence of the silicon layer on the surface reduces the oxidation rate of SiGe in the channel to some extent.

The semiconductor device in the embodiments of the present disclosure may be a memory chip, such as a Dynamic Random Access Memory (DRAM), and of course, it may also be other semiconductor devices, which are not to be enumerated here. Reference may be made to the above beneficial effects of the semiconductor device structure for the beneficial effects of the semiconductor device, which are not to be repeated here.

It is to be noted that, steps of the method in the present disclosure are described in a particular order in the accompanying drawings. However, this does not require or imply to execute these steps necessarily according to the particular order, or this does not mean that the expected result cannot be implemented unless all the shown steps are executed. Additionally, some steps may be omitted, a plurality of steps may be combined into one step for execution, and/or one step may be decomposed into a plurality of steps for execution, which shall be considered as a part of the present disclosure.

It is to be understood that the present disclosure does not limit its application to the detailed structure and arrangement of the components proposed in this specification. The present disclosure can have other embodiments and can be implemented and carried out in various ways. The foregoing variations and modifications fall within the scope of the present disclosure. It is to be understood that the present disclosure disclosed and defined in this specification extends to all fungible combinations of two or more individual features that are mentioned or apparent from the text and/or drawings. All of these different combinations constitute various fungible aspects of the present disclosure. The embodiments in this specification explain the best modes known for practicing the present disclosure and will enable those skilled in the art to utilize the present disclosure.

What is claimed is:

1. A method for fabricating a semiconductor device, wherein the fabrication method comprises:
providing a substrate;
forming an active layer on a side of the substrate;
forming, on a side of the active layer away from the substrate, a shielding layer covering the active layer; and
performing ion implantation of a first element above the shielding layer to form a heavily doped layer on a surface of the active layer;
wherein an implantation depth corresponding to a peak implantation concentration of the first element is equal to a thickness of the shielding layer.

2. The fabrication method according to claim 1, wherein the substrate comprises the first element, the active layer comprising the first element and a second element, and a content of the first element being greater than a content of the second element in the active layer.

3. The fabrication method according to claim 2, wherein both the first element and the second element comprise silicon or germanium.

4. The fabrication method according to claim 2, wherein forming the active layer comprises:
depositing on the substrate for a first preset time by means of chemical vapor deposition using a gas containing the first element and a gas containing the second element to form the active layer.

5. The fabrication method according to claim 1, wherein the thickness of the shielding layer ranges from 1 nm to 500 nm.

6. The fabrication method according to claim 1, wherein a material for forming the shielding layer comprises a combination of one or more of oxides, nitrides, oxynitrides, oxycarbides, hydroxides or amorphous carbons.

7. The fabrication method according to claim 1, wherein forming the heavily doped layer comprises:
implanting ions corresponding to the first element into the shielding layer at a preset angle by means of ion implantation technology using the gas containing the first element.

8. The fabrication method according to claim 7, wherein a dose of the ion implantation is 10¹⁵ to 10¹⁸/cm², an energy of the ion implantation being 1 keV to 500 keV, and a temperature of the ion implantation being −40° C. to 140° C.

9. The fabrication method according to claim 1, further comprising: performing thermal annealing on the semiconductor structure after the ion implantation is completed, an annealing temperature being 800° C. to 1,100° C., and annealing time being 1 s to 30 s.

10. The fabrication method according to claim 9, further comprising: removing the shielding layer after the thermal annealing; and
forming an interface layer on the side of the active layer away from the substrate, and sequentially forming a dielectric layer and a gate stack layer above the interface layer.

11. A semiconductor device structure fabricated by means of the fabrication method according to claim 1, wherein the semiconductor device structure comprises:
a substrate;
an active layer positioned on the substrate;
a heavily doped layer positioned on a surface of the active layer away from the substrate; and
an interface layer positioned above the surface of the active layer, the heavily doped layer being positioned between the active layer and the interface layer.

12. The semiconductor device structure according to claim 11, wherein a thickness of the heavily doped layer is smaller than a thickness of the interface layer.

13. The semiconductor device structure according to claim 11, wherein a thickness of the interface layer is smaller than a thickness of the active layer.

14. The semiconductor device structure according to claim 11, further comprising a dielectric layer and a gate stack layer, wherein the dielectric layer is positioned above the interface layer, the gate stack layer being positioned above the dielectric layer.

15. The semiconductor device structure according to claim 11, wherein the substrate comprises a silicon substrate, the active layer comprising a silicon germanium layer, and the heavily doped layer comprising a silicon layer.
